(19) United States
(12) Patent Application Publication
(10) Pub. No.: US 2025/0273568 A1
(43) Pub. Date: Aug. 28, 2025

(54) MIXED PITCH LEVELS FOR BACK-END-OF-LINE WIRING LAYERS

(71) Applicant: International Business Machines Corporation, Armonk, NY (US)

(72) Inventors: Brent A. Anderson, Jericho, VT (US); Nicholas Anthony Lanzillo, Wynantskill, NY (US); Albert M. Chu, Nashua, NH (US); David Wolpert, Poughkeepsie, NY (US); Ruilong Xie, Niskayuna, NY (US); Lawrence A. Clevenger, Saratoga Springs, NY (US)

(21) Appl. No.: 18/586,732

(22) Filed: Feb. 26, 2024

(51) Int. Cl. H01L 23/528; H01L 21/768; H01L 23/522; H01L 27/092

(52) U.S. Cl. CPC H01L 23/5283; H01L 21/76877; H01L 23/5226; H10D 84/853

(57) ABSTRACT

A semiconductor structure includes at least one interconnect wiring level between a first device layer and a second device layer, wherein the at least one interconnect wiring level includes a first set of wires that are spaced apart from each other at a first minimum pitch, and a second set of wires that are spaced apart from each other at a second minimum pitch that is different than the first minimum pitch. The first set of wires comprises a first cross-sectional area and the second set of wires comprises a second cross-sectional area that is different than the first cross-sectional area.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments described herein provide techniques for forming mixed pitch levels for back-end-of-line wiring layers.

In one embodiment, a semiconductor structure comprises at least one interconnect wiring level between a first device layer and a second device layer, where the at least one interconnect wiring level includes a first set of wires that are spaced apart from each other at a first minimum pitch, and a second set of wires that are spaced apart from each other at a second minimum pitch that is different than the first minimum pitch. The first set of wires comprises a first cross-sectional area and the second set of wires comprises a second cross-sectional area that is different than the first cross-sectional area.

In another embodiment, a semiconductor structure comprises a first device layer, a second device layer stacked over the first device layer, and a plurality of interconnect wiring levels between the first device layer and the second device layer. The plurality of interconnect wiring levels includes at least one interconnect wiring level between the first device layer and the second device layer. The at least one interconnect wiring level includes a first set of wires that are spaced apart from each other at a first minimum pitch, and a second set of wires that are spaced apart from each other at a second minimum pitch that is different than the first minimum pitch. The first set of wires includes a first cross-sectional area, and the second set of wires includes a second cross-sectional area that is different than the first cross-sectional area.

In another embodiment, a method includes forming a first device layer, forming a plurality of interconnect wiring levels adjacent to the first device layer, where at least one interconnect wiring level comprises a first set of wires that are spaced apart from each other at a first minimum pitch and a second set of wires that are spaced apart from each other at a second minimum pitch that is different than the first minimum pitch. The first set of wires comprises a first cross-sectional area, and the second set of wires comprises a second cross-sectional area that is different than the first cross-sectional area. The method also includes forming a second device layer adjacent such that the plurality of interconnect wiring levels is disposed between the first device layer and the second device layer.

These and other features and advantages of embodiments described herein will become more apparent from the accompanying drawings and the following detailed description.

### BRIEF DESCRIPTION OF THE DRAWINGS

FIG. 1 depicts a cross-sectional view of a semiconductor structure including middle Back-End-Of-Line (BEOL) wiring layers between first and second device layers, according to an illustrative embodiment.

FIG. 2 depicts a cross-sectional view of a mixed pitch interconnect wiring level, according to an illustrative embodiment.

FIG. 3 depicts a cross-sectional view of a BEOL structure at an initial state, according to an illustrative embodiment.

FIG. 4 depicts a cross-sectional view of a BEOL structure following formation of a first dielectric layer and vias, according to an illustrative embodiment.

FIG. 5 depicts a cross-sectional view of a BEOL structure following formation of a second dielectric layer and a first set of interconnect lines, according to an illustrative embodiment.

FIG. 6 depicts a cross-sectional view of a BEOL structure following a masking and etching process for forming a second set of interconnect lines, according to an illustrative embodiment.

FIG. 7 depicts a cross-sectional view of a BEOL structure following formation of the second set of interconnect lines, according to an illustrative embodiment.

FIG. 8 depicts a cross-sectional view of a BEOL structure where a first set of interconnect lines is positioned at a middle of a second set of interconnect lines, according to an illustrative embodiment.

FIG. 9 depicts a cross-sectional view of a BEOL structure where a first set of interconnect lines is positioned at a bottom of a second set of interconnect lines, according to an illustrative embodiment.

FIG. 10 depicts a cross-sectional view of a BEOL structure where a first set of interconnect lines with a relatively higher aspect ratio than a second set of interconnect lines, according to an illustrative embodiment.

FIG. 11 depicts a cross-sectional view of a BEOL structure with different pitches and various via connections, according to an illustrative embodiment.

### DETAILED DESCRIPTION

Illustrative embodiments may be described herein in the context of illustrative methods for forming middle back-end-of-line (BEOL) wiring layers with mixed pitch levels between first and second device layers, along with illustrative apparatus, systems and devices formed using such methods. However, it is to be understood that embodiments are not limited to the illustrative methods, apparatus, systems and devices but instead are more broadly applicable to other suitable methods, apparatus, systems and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A field-effect transistor (FET) is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm and beyond. A general process flow for formation of a nanosheet stack involves selectively removing sacrificial layers, which may be formed of silicon germanium (SiGe), between sheets of channel material, which may be formed of silicon (Si).

For continued scaling (e.g., to 2.5 nm and beyond), next generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next generation stacked FET structures provide improved track height scaling, leading to structural gains (e.g., such as 30-40%) for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. There is, however, a continued desire for further scaling and reducing the size of FETs.

As discussed above, various techniques may be used to reduce the size of FETs, including through the use of fin-shaped channels in FinFET devices, through the use of stacked nanosheet channels formed over a semiconductor substrate, and next-generation stacked FET devices.

Although some embodiments of the present disclosure are discussed in connection with nanosheet stacks, the embodiments of the present disclosure are not necessarily limited thereto, and may similarly apply to nanowire stacks.

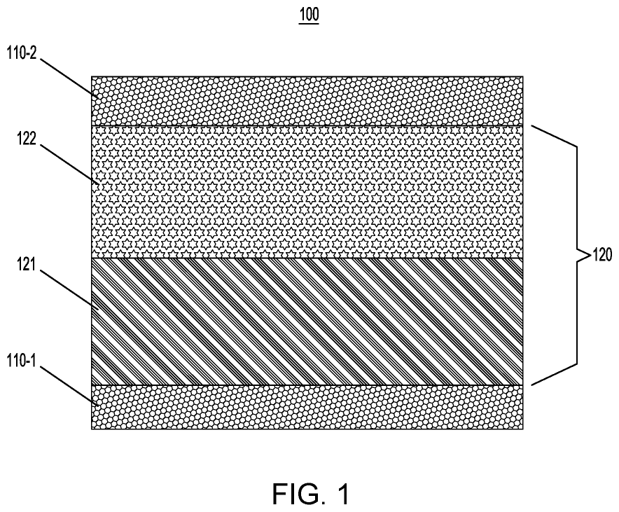

FIG. 1 depicts a cross-sectional view of a semiconductor structure 100 including a middle BEOL wiring configuration 120 with a first set of interconnect wiring layers 121 and a second set of one or more interconnect wiring layers 122 between a first device layer 110-1 and a second device layer 110-2 (collectively “device layers 110”). As an example, the first set of interconnect wiring layers 121 can be associated with local interconnects, and the second set of interconnect wiring layers 121 can be associated with global interconnects. The first and second sets of interconnect wiring layers 121 and 122 are formed in for, example, one or more dielectric layers (not shown) comprising, for example, silicon oxide (SiOₓ) (where x is for example, 2, 1.99 or 2.01), silicon oxycarbide (SiOC), silicon oxycarbonitride (SiOCN) or some other dielectric material.

In a non-limiting example embodiment, the first and second device layers 110 comprise stacked nanosheet transistors comprising a plurality of gate structures alternately stacked with a plurality of channel layers, and source/drain regions disposed between the nanosheet stacks comprising the gate structures and channel layers. However, the embodiments are not limited to stacked nanosheet transistors in the first and second device layers 110, and may comprise other types of transistors including, but not necessarily limited to, planar FETs, vertical transport FETs (VTFETs) or other types of transistors.

In an illustrative embodiment, the first device layer 110-1 is formed, followed by formation of the middle BEOL wiring configuration 120. A layer of semiconductor material (e.g., silicon, III-V, II-V compound semiconductor materials or other like semiconductor materials) is bonded to the middle BEOL wiring configuration 120, and the second device layer 110-2 is formed.

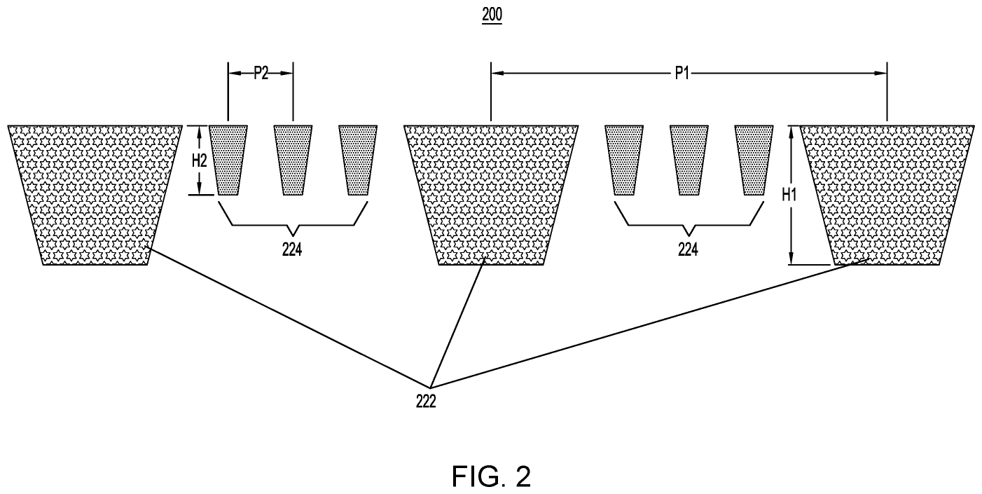

The middle BEOL wiring configuration 120 comprises two or more levels of interconnect wiring located between the first device layer 110-1 and the second device layer 110-2. It is assumed that two or more of the levels of interconnect wiring levels in the middle BEOL wiring configuration have mixed pitches, as explained in more detail in connection with FIG. 2, for example.

In some embodiments, a frontside BEOL metallization structure (not shown) can include one or more frontside BEOL metallization layers formed on the second device layer 110-2. The frontside BEOL metallization layers can comprise, for example, wiring that is present on a chip, including, for example, multiple metal levels corresponding to circuit wiring, bussing, power distribution, input-output (I/O), etc. In illustrative embodiments, the frontside BEOL metallization structure includes frontside BEOL interconnects formed on the frontside BEOL metallization layers. The frontside BEOL metallization layers contact the frontside BEOL interconnects. A carrier wafer is bonded to the frontside BEOL interconnects. The frontside BEOL interconnects include various BEOL interconnect structures which may electrically connect to one or more frontside BEOL metallization layers. A carrier wafer can be formed over the frontside BEOL interconnects using a wafer bonding process, such as dielectric-to-dielectric bonding. The carrier wafer comprises semiconductor material including, but not limited to, silicon (Si), III-V, II-V compound semiconductor materials or other like semiconductor materials. In addition, multiple layers of the semiconductor materials can be used as the semiconductor material of the carrier wafer. Using the carrier wafer, the semiconductor structure 100 may be “flipped” (e.g., rotated 180 degrees) so that the structure is inverted for backside processing.

In some embodiments, a backside BEOL metallization structure (not shown) can include backside BEOL metallization layers. The backside BEOL metallization layers can comprise, for example, backside power rails or other voltage or signal sources.

As used herein, “frontside” or “first side” refers to a side corresponding to the second device layer 110-2 and frontside BEOL metallization layers. As used herein, “backside” or “second side” refers to a side corresponding to the first device layer 110-1 and the backside BEOL metallization layers (e.g., opposite the “frontside”).

As noted hereinabove, the first and second device layers 110 can comprise, for example, stacked nanosheet transistors. For example, the first device layer 110-1 may comprise stacked nanosheet transistors having a first doping type (e.g., p-type) and the second device layer 110-2 may comprise stacked nanosheet transistors having a second doping type (e.g., n-type). Although described in terms of stacked nanosheet transistors, the first and second device layers 110 are not limited thereto, and may comprise different types of devices such as, but not necessarily limited to, other types of transistors (e.g., planar transistors, FinFETs, VTFETs), capacitors, and/or other devices.

Referring now to FIG. 2, this figure shows an example of a mixed pitch interconnect wiring level 200 (e.g., corresponding to one of the levels from the first and second sets of interconnect wiring layers 121 and 122). As an example, a first set of wires 222 can facilitate use for power delivery and longer distance clock, bus and signal wiring, and the set of wires 224 can facilitate local connections of the wires (e.g., to the first device layer 110-1 and/or the second device layer 110-2).

The mixed pitch interconnect wiring level 200 in the FIG. 2 example includes the first set of wires 222 (or lines) having a first height (H1) and first pitch (P1), and a second set of wires 224 having a second height (H2) and a second pitch (P2). It is assumed that P2 is relatively larger than P1 in the mixed pitch interconnect wiring level 200 in FIG. 2. For example, in some embodiments, P1 can be at least two times the size of P2.

The term “pitch” generally refers to a dimensional distance (e.g., length, width, or height) associated with one or more features. Such a dimensional distance can be defined in many different ways. In some cases, pitch can be a total length of a feature and a space next to the feature. In other cases, and as illustratively used herein, pitch can refer to a dimensional distance between centers of two features at a same wiring level. Accordingly, the term “minimum pitch” typically refers to the smallest pitch that can practically be realized based on techniques used to fabricate the feature(s), e.g., limitations of lithographic capabilities, limitations of etching processes, etc. Thus, the term “minimum pitch” as used herein is not intended to be limiting but rather can widely vary depending on the nature of the feature(s) and the fabrication techniques used to form the feature(s). By way of example, the minimum pitch for the first set of wires 222 corresponds to the minimum spacing between two wires in the first set of wires 222, and the minimum pitch for the second set of wires 224 corresponds to the minimum spacing between two wires in the second set of wires 224.

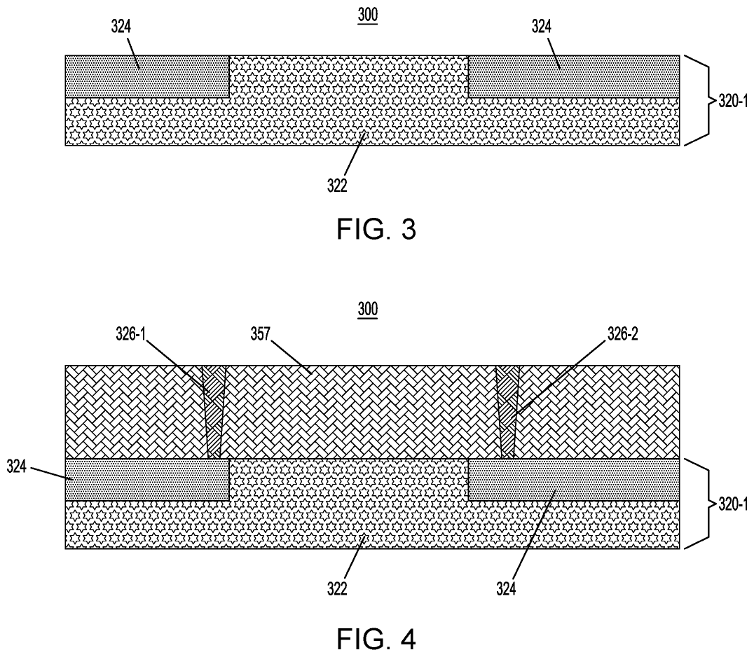

FIGS. 3-7 show cross-sectional views of a BEOL structure 300 at different stages of a BEOL process in accordance with illustrative embodiments. The BEOL structure 300 shown in FIG. 3 includes an interconnect wiring layer 320-1. It is assumed that the interconnect wiring layer 320-1 includes wires 322 and 324, where wires 322 have a relatively larger pitch than wires 322.

FIG. 4 shows the BEOL structure 300 following formation of vias 326-1 and 326-2 in portions of a first inter-layer dielectric (ILD) layer 357, according to an illustrative embodiment. For example, the first ILD layer 357 can be deposited using deposition techniques such as, for example, CVD, PECVD, RFCVD, PVD, ALD, MBD, PLD, and/or LSMCD, followed by a planarization process, such as, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), liquid source misted chemical deposition (LSMCD), sputtering and/or plating, followed by a planarization process such as, chemical mechanical planarization (CMP). The first ILD layer 357 may comprise, for example, SiOₓ, SiOC, SiOCN or some other dielectric material.

A mask can be formed on parts of the first ILD layer 357 where the vias 326-1 and 326-2 are to be formed. The exposed portions of the first ILD layer 357 can then be removed using, for example, a dry etching process using a reactive-ion etch (RIE) or ion beam etch (IBE) process, a wet chemical etch process or a combination of these etching processes. A dry etch may be performed using a plasma. Such wet or dry etch processes include, for example, IBE by Ar/CHF₃ based chemistry.

Metal layers are deposited in the openings to form the vias 326-1 and 326-2. The metal layers comprise, for example, a silicide layer, such as Ni, Ti, NiPt, etc., a metal adhesion layer, such as TiN, and a conductive metal fill layer, such as W, Al, Co, Ru, etc., and can be deposited using, for example, a deposition technique such as CVD, PECVD, RFCVD, PVD, ALD, molecular MBD, PLD, LSMCD, sputtering and/or plating, followed by a planarization process such as, CMP to remove excess portions of the metal layers from on top of dielectric layers.

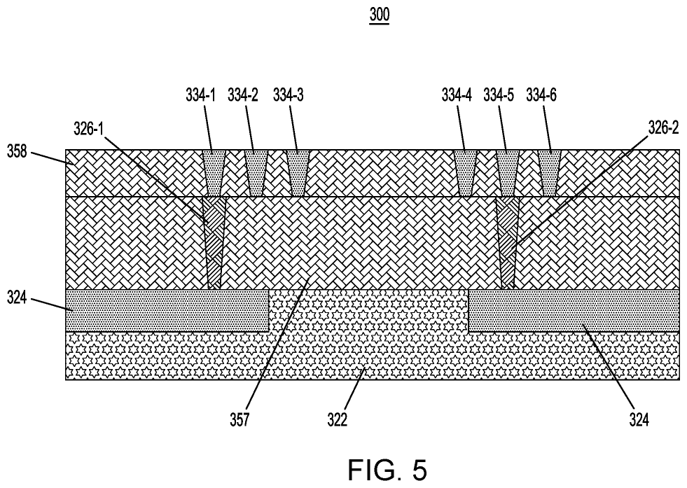

FIG. 5 depicts a cross-sectional view of the BEOL structure 300 following formation of interconnect wires 334-1, 334-2, 334-3, 334-4, 334-5, and 334-6 (collectively “interconnect wires 334”), according to an illustrative embodiment. More specifically, another ILD layer, a second ILD layer 358, can be formed on the first ILD layer 357 and vias 326-1 and 326-2. One or more trenches can then be formed in the second ILD layer 358. Trenches may be opened in the second ILD layer 358 using, for example, lithography followed by reactive ion etching (RIE), for example. The interconnect wires 334 are then formed by filling the one or more trenches with conductive material, such as, for example, electrically conductive material including, but not necessarily limited to, tungsten, cobalt, zirconium, tantalum, titanium, aluminum, ruthenium, and/or copper.

A liner layer (not shown) including, for example, titanium and/or titanium nitride, may be formed on side and bottom surfaces of the trenches before filling the trenches with the conductive material. Deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP.

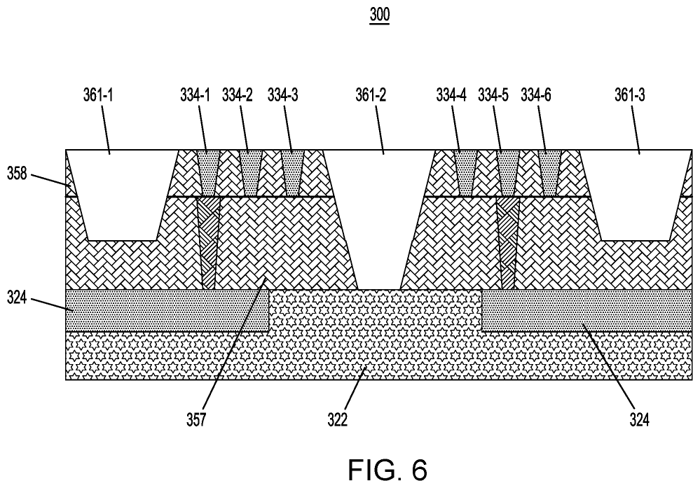

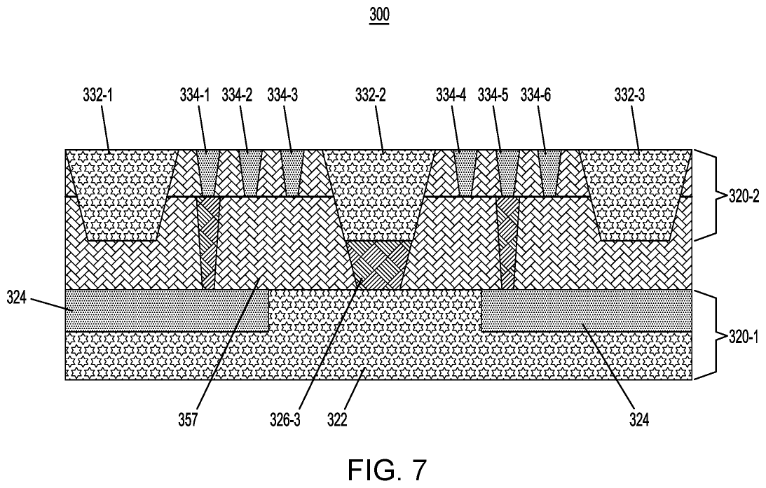

FIG. 6 depicts a cross-sectional view of the BEOL structure following a masking and etching process for forming a second set of interconnect wires, according to an illustrative embodiment. For example, one or more masks can be formed on parts of the second ILD layer 358 where additional wires are to be formed (e.g., interconnect wires 332-1, 332-3, and 332-3 shown in FIG. 7). The exposed portions of the second ILD layer 358 can be removed to form vacant areas 361-1, 361-2, and 361-3 using, for example, a dry etching process using a RIE or IBE process, a wet chemical etch process or a combination of these etching processes. A dry etch may be performed using a plasma. Such wet or dry etch processes include, for example, IBE by Ar/CHF₃ based chemistry.

FIG. 7 depicts a cross-sectional view of a BEOL structure 300 following formation of the interconnect wires 332-1, 332-3, and 332-3 (collectively “interconnect wires 332”) within the respective vacant areas 361-1, 361-2, and 361-3. For example, the interconnect wires 332 can be formed using similar techniques as previously described for the interconnect wires 334. In some embodiments, the interconnect wires 332 can be formed using a Dual-Damascene process. Generally, a Dual-Damascene process can pattern vias and trenches such that the vias and trenches can be filled with conductive material at substantially the same time. For example, the Dual-Damascene process can include forming the vacant area 361-2. The vacant area 361-2 can be filled with a conductive material so as to form via 326-3 and the interconnect wire 332-2. The deposition of the conductive material can be performed using one or more deposition techniques, including, but not necessarily limited to, CVD, PECVD, PVD, ALD, MBD, PLD, LSMCD, and/or spin-on coating, followed by planarization using a planarization process, such as, for example, CMP. Those skilled in the art will appreciate that the wire 322 is visible in the cross-sectional view of FIG. 7, but the wire 322 is located physically behind wires 324 in this example.

Accordingly, the BEOL structure 300 in FIG. 7 includes an interconnect wiring layer 320-2 that is formed on the interconnect wiring layer 320-1, where both the interconnect wiring layers 320-1 and 320-2 comprise wires with different pitch sizes. As non-limiting examples, the minimum pitch between interconnect wires 334 can be in the range of 20 nm to 200 nm, and the minimum pitch between interconnect wires 332 can be in the range of 100 nm to 2000 nm.

The vias 326-1, 326-2, 326-3 provide connections between the interconnect wiring layer 320-2 and the interconnect wiring layer 320-1.

It is to be appreciated that the BEOL structure 300, in some embodiments, can include additional interconnect wiring layers. One or more of the additional interconnect wiring layers can have wires with different pitch sizes and/or have wires with the same pitch size.

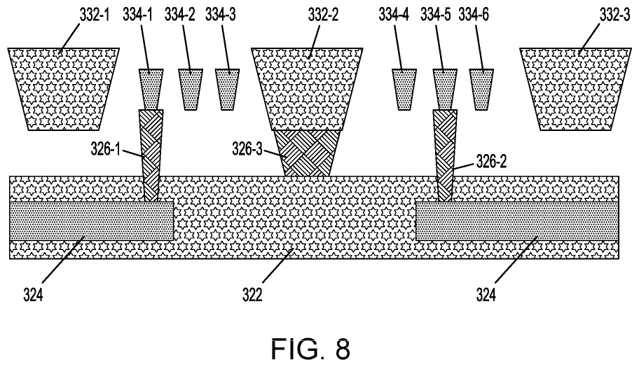

Additional arrangements of the BEOL structure 300 are now described in connection with FIGS. 8-11. It is noted that the first ILD layer 357 and the second ILD layer 358 are not explicitly shown in FIG. 8-11.

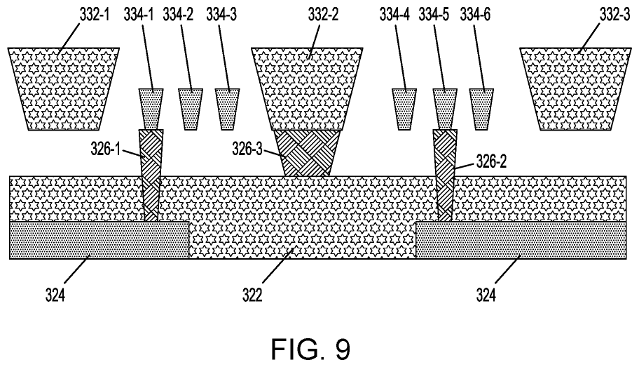

When forming the BEOL structure 300 shown in FIG. 7, it is possible that the interconnect wires 334 can be damaged due to a CMP process performed on the interconnect wires 332, for example, and can also add variability to the thickness of interconnect wires 334. FIGS. 8 and 9 show alternative arrangements of the BEOL structure 300 shown in FIG. 7, which can help mitigate such damage. In the BEOL structure 300 shown in FIG. 8, the top surfaces of interconnect wires 332 are formed below the top surfaces of interconnect wires 334, and in the BEOL structure 300 shown in FIG. 9, the top surfaces of interconnect wires 332 are formed below a middle of the interconnect wires 334. FIGS. 8-9 also show that the position of wires 324 with respect to wires 322 in the interconnect wiring layer 320-1 can be adjusted to account for the different alignments. Recessing the interconnect wires 334 can avoid such issues and can also reduce chances of shorting since the flare of interconnect wires 332 creates additional spacing to interconnect wires 334. Recessing the interconnect wires 334 can also allow the height of the vias 326-1 and 326-2 to be reduced in some embodiments. In at least some embodiments, the interconnect wires 332 and 334 and/or liners corresponding to the interconnect wires 332 and 334 can be formed of different metals. The different alignments shown in FIGS. 8 and 9 can improve manufacturability of the steps by isolating the processing for the interconnect wires 332 and 334.

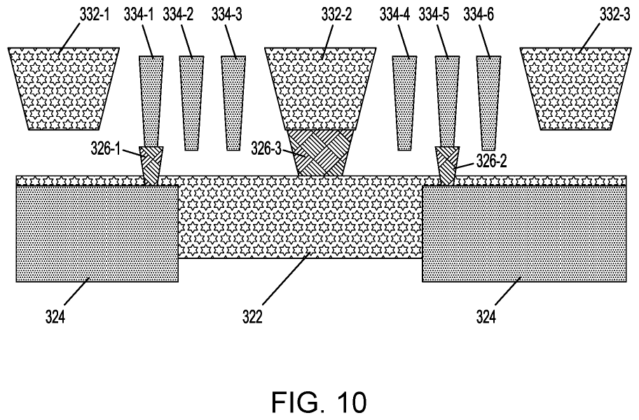

FIG. 10 shows another alternative arrangement of the BEOL structure 300, where the interconnect wires 334 have a different aspect ratio relative to the example shown in FIG. 7. The term “aspect ratio” in this context and elsewhere herein refers to a value equal to the height of a wire divided by the width of the wire. As shown in FIG. 10, the aspect ratio of interconnect wires 334 is greater than the aspect ration of the interconnect wires 332. According to at least one embodiment, the aspect ratio of the interconnect wires 334 can be at least three times greater than the aspect ratio of the interconnect wires 332. The embodiment shown in FIG. 10 can help reduce the height of the vias 326-1 and 326-2 and can also lower the resistance of interconnect wires 334.

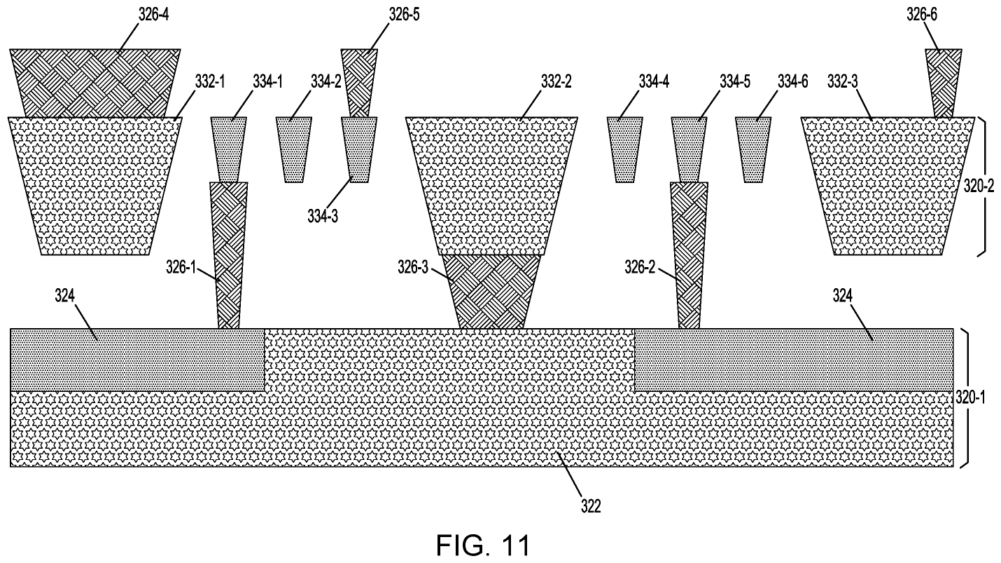

FIG. 11 depicts a cross-sectional view of a BEOL structure 300 showing additional via connections, according to an illustrative embodiment. Specifically, the BEOL structure 300 shown in FIG. 11 includes vias 326-4, 326-5, and 326-6, that are formed above the interconnect wiring layer 320-2. The vias 326-4, 326-5, and 326-6 can be formed within portions of another ILD layer that is formed above the interconnect wiring layer 320-2 using similar techniques as described above. The via 326-4 is assumed to be relatively larger (e.g., wider) than vias 326-5 and 326-6, thereby resulting in a lower resistance, and thus is suitable for global connections, for example. The vias 326-5 and 326-6 provide connections to interconnect wire 334-3 and interconnect wire 332-3, respectively. At least some of the vias 326-4, 326-5, and 326-6 can provide connections to a topside device layer (e.g., the second device layer 110-2), for example.

In some embodiments, the interconnect wires 332 with the wider pitches can be used for connections to global power distribution elements (e.g., power rails), long distance signals, and/or long distance clocking. For example, in illustrative embodiments, backside power delivery network (BSPDN) layers are formed on a backside power rail. BSPDN layers include various BSPDN structures such as, but not necessarily limited to, interconnects in a power supply path from voltage regulator modules (VRMs) to circuits. The interconnects can comprise, for example, power and ground planes in circuit boards, cables, connectors and capacitors associated with a power supply. Backside power delivery prevents BEOL routing congestion, resulting in power performance benefits. The interconnect wires 334 with the smaller (e.g., tighter) pitches can be used for connections to device layers (e.g., the first and second device layers 110).

Semiconductor devices and methods for forming the same in accordance with the above-described techniques can be employed in various applications, hardware, and/or electronic systems. Suitable hardware and systems for implementing embodiments may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments. Given the teachings provided herein, one of ordinary skill in the art will be able to contemplate other implementations and applications of embodiments.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

As noted above, the embodiments provide techniques and structures for forming middle BEOL wiring layers with mixed pitch sizes between first and second device layers. In illustrative embodiments, a given BEOL wiring layer includes a first set of wires having a small pitch and a second set of wires having a large pitch. Such BEOL wiring layers advantageously enable formation of simplified contacts to middle BEOL layers (e.g., connection between the second device layer 110-2 and the middle BEOL wiring configuration 120). Further, using wires with different sizes and pitches within the same BEOL wiring layer can advantageously reduce the stack height of the BEOL wiring layers, thereby simplifying configurations and lowering costs.

In some embodiments, a semiconductor structure comprises at least one interconnect wiring level between a first device layer and a second device layer, where the at least one interconnect wiring level includes a first set of wires that are spaced apart from each other at a first minimum pitch, and a second set of wires that are spaced apart from each other at a second minimum pitch that is different than the first minimum pitch. The first set of wires comprises a first cross-sectional area and the second set of wires comprises a second cross-sectional area that is different than the first cross-sectional area.

The second device layer may be stacked above the first device layer. The second minimum pitch may be at least two times the first minimum pitch. The second cross-sectional area may be at least two times the first cross-sectional area. A top surface of each wire in the first set may be positioned below a top surface of each wire in the second set. A top surface of each wire in the first set may be positioned below a middle of each wire in the second set. An aspect ratio of each wire in the first set may be at least three times an aspect ratio of each wire in the second set. The at least one interconnect wiring level may be adjacent to the second device layer, and the semiconductor structure may include first and second vias connected to the at least one interconnect wiring level, where the first via is a different size than the second via. The semiconductor structure may include a backside back-end-of-line metallization structure under the first device layer, and a frontside back-end-of-line metallization structure over the second device layer.

In some embodiments, a semiconductor structure comprises a first device layer, a second device layer stacked over the first device layer, and a plurality of interconnect wiring levels between the first device layer and the second device layer. The plurality of interconnect wiring levels includes at least one interconnect wiring level between the first device layer and the second device layer. The at least one interconnect wiring level includes a first set of wires that are spaced apart from each other at a first minimum pitch, and a second set of wires that are spaced apart from each other at a second minimum pitch that is different than the first minimum pitch. The first set of wires includes a first cross-sectional area, and the second set of wires includes a second cross-sectional area that is different than the first cross-sectional area.

At least another one of the interconnect wiring levels in the plurality interconnect wiring levels may include a third set of wires that are spaced apart from each other at the first minimum pitch and a fourth set of wires that are spaced apart from each other at the second minimum pitch.

The second device layer may be stacked above the first device layer. The second minimum pitch may be at least two times the first minimum pitch. The second cross-sectional area may be at least two times the first cross-sectional area. A top surface of each wire in the first set may be positioned below a top surface of each wire in the second set. An aspect ratio of each wire in the first set may be at least three times an aspect ratio of each wire in the second set. The at least one interconnect wiring level may be adjacent to the second device layer, and the semiconductor structure may include first and second vias connected to the at least one interconnect wiring level, where the first via is a different size than the second via. The semiconductor structure may include a backside back-end-of-line metallization structure under the first device layer, and a frontside back-end-of-line metallization structure over the second device layer. The first device layer may include one or more transistors corresponding to a first doping type, and the second device layer may include one or more transistors corresponding to a second doping type.

In some embodiments, a method includes forming a first device layer, forming a plurality of interconnect wiring levels adjacent to the first device layer, where at least one interconnect wiring level comprises a first set of wires that are spaced apart from each other at a first minimum pitch and a second set of wires that are spaced apart from each other at second minimum pitch that is different than the first minimum pitch. The first set of wires comprises a first cross-sectional area, and the second set of wires comprises a second cross-sectional area that is different than the first cross-sectional area. The method also includes forming a second device layer such that the plurality of interconnect wiring levels is disposed between the first device layer and the second device layer. The method may include forming a first via for connecting the first device layer to a backside back-end-of-line metallization structure adjacent to the first device layer and forming a second via for connecting the second device layer to a frontside back-end-of-line metallization structure adjacent to the second device layer. The method may include forming at least one sacrificial placeholder (e.g., comprising SiGe, III-V semiconductor material or other semiconductor material) to be used to form a via for connecting the first device layer to a backside back-end-of-line metallization structure under the first device layer.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
at least one interconnect wiring level between a first device layer and a second device layer, wherein the at least one interconnect wiring level comprises:
a first set of wires that are spaced apart from each other at a first minimum pitch; and
a second set of wires that are spaced apart from each other at a second minimum pitch that is different than the first minimum pitch, and wherein the first set of wires comprises a first cross-sectional area, and the second set of wires comprises a second cross-sectional area that is different than the first cross-sectional area.

2. The semiconductor structure of claim 1, wherein the second device layer is stacked above the first device layer.

3. The semiconductor structure of claim 1, wherein at least one of:
the second minimum pitch is at least two times the first minimum pitch; and
the second cross-sectional area is at least two times the first cross-sectional area.

4. The semiconductor structure of claim 1, wherein a top surface of each wire in the first set is positioned below a top surface of each wire in the second set.

5. The semiconductor structure of claim 1, wherein a top surface of each wire in the first set is positioned below a middle of each wire in the second set.

6. The semiconductor structure of claim 1, wherein an aspect ratio of each wire in the first set is at least three times an aspect ratio of each wire in the second set.

7. The semiconductor structure of claim 1, wherein the at least one interconnect wiring level is adjacent to the second device layer, and wherein the semiconductor structure comprises first and second vias connected to the at least one interconnect wiring level, wherein the first via is a different size than the second via.

8. The semiconductor structure of claim 1, further comprising:
a backside back-end-of-line metallization structure under the first device layer; and
a frontside back-end-of-line metallization structure over the second device layer.

9. A semiconductor structure comprising:
a first device layer;
a second device layer stacked over the first device layer; and
a plurality of interconnect wiring levels between the first device layer and the second device layer, wherein the plurality of interconnect wiring levels comprises at least one interconnect wiring level between the first device layer and the second device layer, wherein the at least one interconnect wiring level comprises:
a first set of wires that are spaced apart from each other at a first minimum pitch; and
a second set of wires that are spaced apart from each other at a second minimum pitch that is different than the first minimum pitch, and wherein the first set of wires comprises a first cross-sectional area, and the second set of wires comprises a second cross-sectional area that is different than the first cross-sectional area.

10. The semiconductor structure of claim 9, wherein at least another one of the interconnect wiring levels in the plurality interconnect wiring levels comprises a third set of wires that are spaced apart from each other at the first minimum pitch and a fourth set of wires that are spaced apart from each other at the second minimum pitch.

11. The semiconductor structure of claim 9, wherein the second device layer is stacked above the first device layer.

12. The semiconductor structure of claim 9, wherein at least one of:
the second minimum pitch is at least two times the first minimum pitch; and
the second cross-sectional area is at least two times the first cross-sectional area.

13. The semiconductor structure of claim 9, wherein a top surface of each wire in the first set is positioned below a top surface of each wire in the second set.

14. The semiconductor structure of claim 9, wherein an aspect ratio of each wire in the first set is at least three times an aspect ratio of each wire in the second set.

15. The semiconductor structure of claim 9, wherein the at least one interconnect wiring level is adjacent to the second device layer, and wherein the semiconductor structure comprises first and second vias connected to the at least one interconnect wiring level, wherein the first via is a different size than the second via.

16. The semiconductor structure of claim 9, further comprising:
a backside back-end-of-line metallization structure under the first device layer; and
a frontside back-end-of-line metallization structure over the second device layer.

17. The semiconductor structure of claim 9, wherein the first device layer comprises one or more transistors corresponding to a first doping type, and wherein the second device layer comprises one or more transistors corresponding to a second doping type.

18. A method, comprising:
forming a first device layer;
forming a plurality of interconnect wiring levels adjacent to the first device layer, wherein at least one interconnect wiring level comprises a first set of wires that are spaced apart from each other at a first minimum pitch and a second set of wires that are spaced apart from each other at a second minimum pitch that is different than the first minimum pitch, and wherein the first set of wires comprises a first cross-sectional area, and the second set of wires comprises a second cross-sectional area that is different than the first cross-sectional area; and
forming a second device layer such that the plurality of interconnect wiring levels is disposed between the first device layer and the second device layer.

19. The method of claim 18, further comprising:
forming a first via for connecting the first device layer to a backside back-end-of-line metallization structure adjacent to the first device layer; and
forming a second via for connecting the second device layer to a frontside back-end-of-line metallization structure adjacent to the second device layer.

20. The method of claim 18, wherein the second minimum pitch is at least two times the first minimum pitch.
